(19) United States
(12) Patent Application Publication
(10) Pub. No.: US 2026/0074155 A1
(43) Pub. Date: Mar. 12, 2026

(54) PLASMA PROCESSING APPARATUS

(71) Applicant: Panasonic Intellectual Property Management Co., Ltd., Osaka (JP)

(72) Inventors: Naoaki TAKEDA, OSAKA (JP); Satoru SUENAGA, NARA (JP)

(21) Appl. No.: 19/313,011

(22) Filed: Aug. 28, 2025

(30) Foreign Application Priority Data
Sep. 6, 2024 (JP) 2024-154275

(51) Int. Cl. H01J 37/32; H05B 3/00; H05B 3/28

(52) U.S. Cl. CPC H01J 37/32449; H01J 37/3211; H05B 3/0019; H05B 3/28; H01J 2237/334; H05B 2203/007; H05B 2203/035

(57) ABSTRACT

A plasma processing apparatus includes a stage, a chamber, a dielectric member, an induction coil, an electric heater, and a power source section. The electric heater includes a first heater that heats a first region of the dielectric member, a second heater that heats a second region of the dielectric member, and a joint that connects these. A first resistor of the first heater extends in a specific direction from a first end to a second end along a first locus corresponding to the first region. A second resistor of the second heater extends in the specific direction from a third end to a fourth end along a second locus corresponding to the second region. The joint connects the first end and the third end. The power source section applies a voltage across the second end and the fourth end.

### CROSS REFERENCE TO RELATED APPLICATION

The present application is based on and claims priority under 35 U.S.C. § 119 with respect to the Japanese Patent Application No. 2024-154275, filed on Sep. 6, 2024, of which entire content is incorporated herein by reference into the present application.

### TECHNICAL FIELD

The present disclosure relates to a plasma processing apparatus.

### BACKGROUND

Conventionally, a plasma processing apparatus for plasma processing of a target object such as a substrate is known (e.g., Japanese Laid-Open Patent Publication No. 2024-007812). Japanese Laid-Open Patent Publication No.2024-007812 discloses “a plasma processing apparatus including: a chamber having an opening; a stage provided in the chamber, on which a target object is placed; a dielectric member that closes the opening; and a plasma generation section that is provided on a side of the dielectric member opposite the chamber and that generates plasma in the chamber by application of high-frequency power, wherein the plasma generation section includes: a first induction coil including one or a plurality of first conductors connected in parallel to one another; and a second induction coil provided so as to surround the first induction coil and including a plurality of second conductors connected in parallel to one another, and the number of the second conductors included in the second induction coil is larger than the number of the first conductors included in the first induction coil”. Japanese Laid-Open Patent Publication No.2024-007812 also discloses provision of a heater for heating the dielectric member.

When high-frequency power is applied to a coil, a high-frequency magnetic field is generated, and the generated magnetic field acts on a feed gas in the chamber to generate plasma. The more efficiently the high-frequency magnetic field acts on the feed gas, the higher plasma generation efficiency becomes. However, a portion of the energy is consumed without contributing to plasma generation due to interference between the magnetic field generated by the coil interfere with and the heater. That is, the electromagnetic interference between the heater and the coil acts as a factor that lowers the plasma generation efficiency.

### SUMMARY

One aspect of the present disclosure relates to a plasma processing apparatus. The plasma processing apparatus includes: a stage on which a target object is to be placed; a chamber that houses the stage and that has an opening; a dielectric member that closes the opening; an induction coil that is provided on a side of the dielectric member opposite the stage and that generates plasma for processing the target object by application of high-frequency power; an electric heater that is provided between the dielectric member and the induction coil and that heats the dielectric member; and a power source section that applies a voltage to the electric heater, wherein the dielectric member has a first region and a second region surrounding the first region, the electric heater includes: a first heater that heats the first region; a second heater that heats the second region; and a joint that connects the first heater and the second heater, the first heater includes a first resistor having a first end and a second end, the second heater includes a second resistor having a third end and a fourth end, the first resistor extends in a specific direction from the first end to the second end along a first locus corresponding to the first region, the specific direction being one of circumferential directions, the second resistor extends in the specific direction from the third end to the fourth end along a second locus corresponding to the second region, the joint connects the first end and the third end, and the power source section applies the voltage between the second end and the fourth end.

### BRIEF DESCRIPTION OF THE DRAWINGS

FIG. 1 is a schematic cross-sectional view of an example of a plasma processing apparatus according to the present disclosure.

FIGS. 2A and 2B are schematic diagrams of the configuration of an electric heater according to a first embodiment, wherein FIG. 2A is a plan view and FIG. 2B is a cross-sectional view taken along a line II-II.

FIG. 3 is a schematic plan view of the configuration of an electric heater in a second embodiment.

FIG. 4 is a schematic plan view of the configuration of an electric heater in a third embodiment.

### DETAILED DESCRIPTION

Embodiments of a plasma processing apparatus according to the present disclosure are described below by way of examples, but the present disclosure is not limited to the examples described below. In the following description, specific numerical values and materials may be exemplified in some cases, but other numerical values and other materials may be adopted as long as the effects of the present disclosure can be obtained.

The plasma processing apparatus according to the present disclosure is an apparatus for plasma processing of a target object. The plasma processing apparatus may be a plasma etching apparatus, a plasma dicer, a plasma ashing apparatus, or a plasma CVD apparatus, for example. The plasma processing apparatus includes a stage, a chamber, a dielectric member, an induction coil, an electric heater, and a power source section.

The target object is placed on the stage. The stage may have a horizontal placement surface on which the target object is to be placed. The stage may have a flow path through which a refrigerant for cooling the target object flows during plasma processing. The stage may include an electrostatic chuck mechanism for chucking the target object. The stage may include a lower electrode to which high frequency power is applied. The target object may be a semiconductor substrate that is singulated by plasma etching, for example. The semiconductor substrate has a plurality of element regions and a division region defining the element regions. The element regions each include a semiconductor layer and a wiring layer, for example. By etching the division region, element chips each including the semiconductor layer and the wiring layer can be obtained. The target object may be placed on the stage with it supported by a carrier. The carrier may be a resin sheet whose outer periphery is held by a frame, for example.

The chamber houses the stage. The chamber has an opening. The chamber may be formed in a hollow cylindrical shape. The chamber may have the opening at the top. The opening may be open upward. The chamber may be made of metal and may be grounded.

The dielectric member closes the opening of the chamber. The dielectric member may be formed in a plate shape having a horizontally extending region. The dielectric member has a first region and a second region surrounding the first region. The first region may be an inner region of the dielectric member, and the second region may be an outer peripheral region of the dielectric member. The first region may be circular. The second region may be annular. The dielectric member may be constituted of ceramics such as quartz, alumina, or aluminum nitride. The dielectric member may be constituted mainly of quartz.

The induction coil is provided on a side of the dielectric member opposite the stage. The induction coil may be provided above the dielectric member. The induction coil generates plasma for processing the target object by application of high-frequency power to the induction coil. The induction coil may generate plasma in the chamber. The induction coil may be constituted of a single coil or a plurality of (e.g., two) coils.

The electric heater is provided between the dielectric member and the induction coil. The electric heater heats the dielectric member. The electric heater includes a first heater that heats the first region of the dielectric member, a second heater that heats the second region of the dielectric member, and a joint that connects the first heater and the second heater. The joint may be constituted of a nichrome wire or a copper plate, for example.

The first heater includes a first resistor having a first end and a second end. The second heater includes a second resistor having a third end and a fourth end. The first resistor extends from the first end to the second end in a specific direction, which is one of the circumferential directions, along a first locus corresponding to the first region. The second resistor extends from the third end to the fourth end in the specific direction along a second locus corresponding to second region. The specific direction may be one of the circumferential directions of the chamber. The specific direction may be either a clockwise direction or a counterclockwise direction when the electric heater is viewed from above. The first resistor and the second resistor may each be formed in a line-like manner. The first resistor and the second resistor may each be constituted of a nichrome wire, for example. At least parts of the first resistor and the second resistor may be covered with an insulator (e.g., mica). The first end of the first heater and the third end of the second heater are connected by the joint. That is, the first end and the third end are in electrical conduction via the joint.

The first locus and the second locus can be arbitrary as long as they extend in the circumferential direction as a whole in the first region and the second region, respectively. The first locus and the second locus may be any looped locus. Either or both at least a part of the first locus and at least a part of the second locus may intersect the specific direction. Either or both a part of the first locus and a part of the second locus may extend in a direction opposite to the specific direction. Either or both at least a part of the first locus or at least a part of the second locus may be straight or curved. At least a part (e.g., the entirety) of the first locus may be included in the first region when viewed from above. At least a part (e.g., the entirety) of the second locus may be included in the second region when viewed from above.

The power source section applies a voltage to the electric heater. The power source section may apply an AC voltage (e.g., an AC voltage at 50 Hz or 60 Hz) or a DC voltage to the electric heater. The power source section applies the voltage across the second end of the first heater and the fourth end of the second heater. In the above configuration, a current path is established in the following order: the power source section, the second end of the first heater, the first end of the first heater, the joint, the third end of the second heater, the fourth end of the second heater, and back to the power source section, all connected in series.

According to the above configuration, when the induction coil generates a high-frequency magnetic field, the induced electromotive force generated in the first heater and the induced electromotive force generated in the second heater, which are generated by the magnetic field, cancel each other. Assume, for example, that the magnetic field generated by the induction coil generates an induced electromotive force in the first resistor of the first heater and the second resistor of the second heater to cause a current to flow in a direction opposite to the specific direction. In this case, the induced electromotive force in the first resistor attempts to generate a current flowing from the second end to the first end, while the induced electromotive force in the second resistor attempts to generate a current flowing from the fourth end to the third end. As described above, since the first end and the third end are connected to each other, the induced electromotive forces of these cancel each other. This cancellation relationship holds regardless of the direction of the magnetic field generated by the induction coil. Therefore, the degree of magnetic coupling between the induction coil and each heater can be reduced to reduce interference therebetween. Thus, a decrease in plasma generation efficiency can be suppressed.

The dielectric member may have an annular groove formed in a surface thereof facing the induction coil, between the first region and the second region. The surface facing the induction coil may be the upper surface of the dielectric member.

At least a part of the induction coil may be located within the annular groove. In this case, when the induction coil is brought further closer to the chamber, the magnetic field generated by the induction coil can act strongly on the feed gas in the chamber, thereby increasing plasma generation efficiency. In addition, since the induction coil is positioned close to the first and second heaters, the techniques of the present disclosure can be more effectively utilized.

The power source section may be connected to the electric heater via a low-pass filter. Since the induced current generated in the electric heater by the magnetic field of the induction coil is a high-frequency current, provision of the low-pass filter between the electric heater and the power source section can inhibit the induced current from flowing into the power source section. The cutoff frequency of the low-pass filter may be 60 Hz or higher and 13.56 MHz or lower, for example.

The joint may extend in the radial direction of the chamber. In this case, the magnetic field generated by the induction coil is less likely to act on the joint, with a result that unnecessary induced electromotive force is less likely to be generated within the electric heater. This means that interference between the induction coil and the electric heater is further suppressed, so that a decrease in plasma generation efficiency can be further suppressed. Note that “the joint extends in the radial direction of the chamber” means not only that the direction in which the joint extends and the radial direction coincide with each other, but also that they form an angle of 10°or less.

According to the present disclosure, as a result of connection between the first resistor and the second resistor being devised, a decrease in the plasma generation efficiency due to interference between the electric heater and the induction coil can be suppressed as described above.

Examples of the plasma processing apparatus according to the present disclosure will be described in detail below with reference to the accompanying drawings. The above-described elements of configuration can be applied to the elements of configuration of the exemplary plasma processing apparatuses described below. The elements of configuration of the exemplary plasma processing apparatuses described below can be altered based on the above description. Further, the matters described below may be applied to the above-described embodiment. Of the elements of configuration of the exemplary plasma processing apparatuses described below, an element of configuration that is not essential to the plasma processing apparatus according to the present disclosure may be omitted. It should be noted that the drawings indicated below are schematic and do not accurately reflect the shape or number of actual members.

### First Embodiment

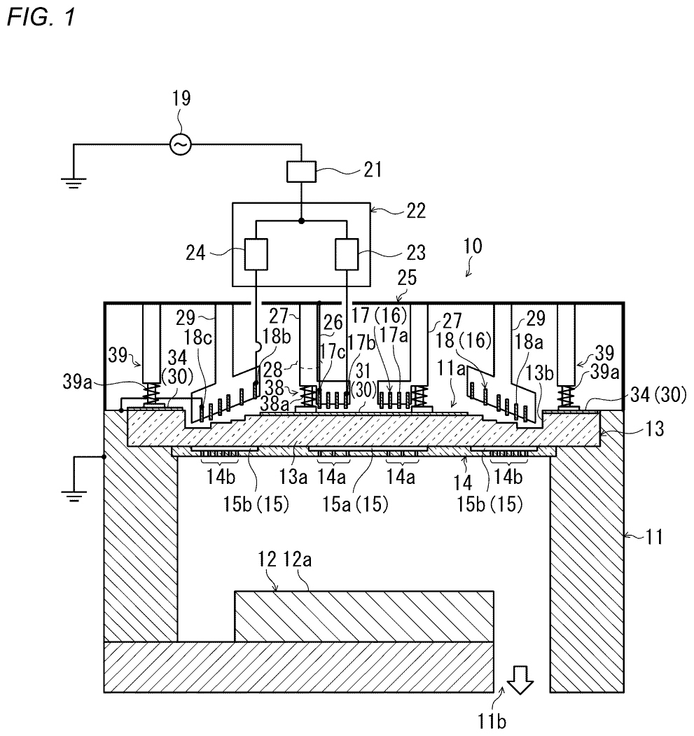

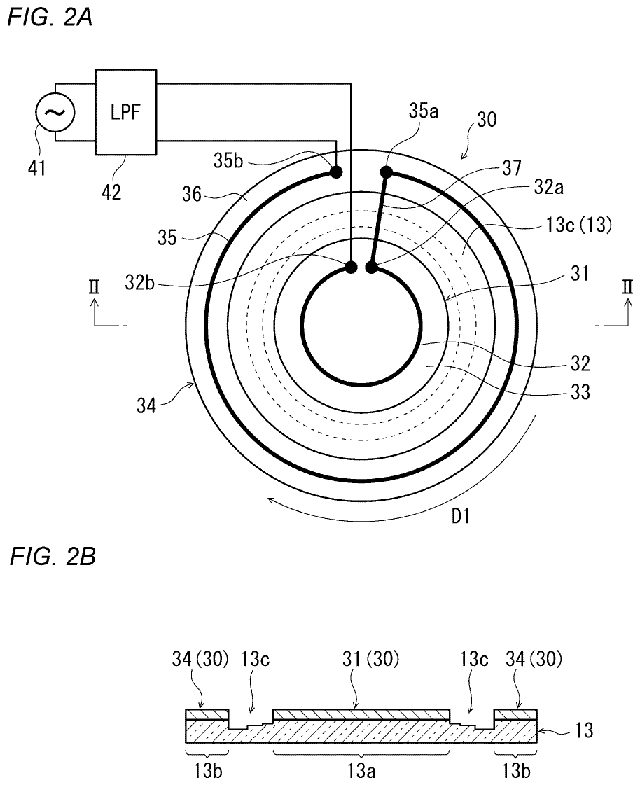

The following describes a first embodiment of the present disclosure. A plasma processing apparatus 10 of the present embodiment is an apparatus for plasma processing of a target object (e.g., a semiconductor substrate). The plasma processing apparatus 10 of the present embodiment is, but is not limited to, a plasma dicer. As illustrated in FIGS. 1, 2A, and 2B, the plasma processing apparatus 10 includes a chamber 11, a stage 12, a dielectric member 13, a cover 14, a gas introduction path 15, a plasma generation section 16, a metal cover 25, a first support column 27, a second support column 29, an electric heater 30, a first pusher 38, a second pusher 39, a high-frequency power supply 19, a matching device 21, a distributor 22, and a power source section 41.

The chamber 11 has an opening 11a at an upper part thereof. The chamber 11 is formed in a hollow cylindrical shape but is not limited thereto. The opening 11a opens upward. The chamber 11 is positioned around the outer periphery of the stage 12 and has an exhaust port 11b for exhausting the feed gas used in the plasma processing. A non-illustrated exhaust system is connected to the exhaust port 11b. The chamber 11 is constituted of a conductive member (e.g., metal). The chamber 11 is grounded.

The stage 12 is positioned in the chamber 11, and a target object is to be placed thereon. The stage 12 has a horizontal placement surface 12a on which the target object is to be placed. The stage 12 has a flow path (not illustrated) through which a refrigerant for cooling the target object flows during the plasma processing. The stage 12 includes an electrostatic chuck mechanism (not illustrated) for chucking the target object. The stage 12 includes a lower electrode (not illustrated) to which high-frequency power is to be applied.

The dielectric member 13 closes the opening 11a of the chamber 11. The dielectric member 13 is formed in a plate shape having a horizontally extending region. The dielectric member 13 has a central region 13a and a peripheral region 13b surrounding the central region 13a. The dielectric member 13 has an annular groove 13c formed in the upper surface between the central region 13a and the peripheral region 13b. The dielectric member 13 is constituted of quartz but is not limited thereto. The central region 13a is an example of the first region. The peripheral region 13b is an example of the second region.

The cover 14 is provided to cover the dielectric member 13 in the chamber 11. The cover 14 covers the lower surface of the dielectric member 13. The cover 14 has a plurality of first gas holes 14a and a plurality of second gas holes 14b. The first gas holes 14a are formed at positions overlapping with the central region 13a of the dielectric member 13. The second gas holes 14b are formed at positions overlapping with the peripheral region 13b of the dielectric member 13. The first gas holes 14a and the second gas holes 14b each penetrate the cover 14 in the thickness direction (vertical direction in FIG. 1). The first gas holes 14a and the second gas holes 14b each communicate with a space in which the stage 12 in the chamber 11 is located. The first gas holes 14a are spaced apart from each other in the radial directions and the circumferential direction. The second gas holes 14b are spaced apart from each other in the radial directions and the circumferential direction. The cover 14 is constituted of aluminum nitride but is not limited thereto.

The gas introduction path 15 is formed between the dielectric member 13 and the cover 14, and the feed gas is introduced into the gas introduction path 15. The gas introduction path 15 includes a first gas introduction path 15a communicating with the first gas holes 14a and a second gas introduction path 15b communicating with the second gas holes 14b. The first gas introduction path 15a and the second gas introduction path 15b are each constituted by a groove formed in the cover 14. The first gas introduction path 15a and the second gas introduction path 15b are separate from each other. The first gas introduction path 15a and the second gas introduction path 15b each communicate with the outside of the chamber 11. A non-illustrated gas source is connected to each of the first gas introduction path 15a and the second gas introduction path 15b.

The plasma generation section 16 includes a first induction coil 17 and a second induction coil 18. The first induction coil 17 and the second induction coil 18 are provided on a side of the dielectric member 13 opposite the stage 12 (in this example, on the upper side of the stage 12). The first induction coil 17 includes a plurality of (two in this case) first conductors 17a connected in parallel to each other. The second induction coil 18 is positioned to surround the first induction coil 17. The second induction coil 18 includes a plurality (in this case, four) of second conductors 18a connected in parallel to each other. A part of the second induction coil 18 is positioned inside the annular groove 13c of the dielectric member 13. Each of the first induction coil 17 and the second induction coil 18 is an example of the induction coil.

One end (a first coil end 17b) of the first conductor 17a constituting the first induction coil 17 is connected to the high-frequency power supply 19 via the distributor 22 and the matching device 21. The other end (a second coil end 17c) of the first conductor 17a constituting the first induction coil 17 is grounded via the chamber 11 which is conductive. One end (a third coil end 18b) of the second conductor 18a constituting the second induction coil 18 is connected to the high-frequency power supply 19 via the distributor 22 and the matching device 21. The other end (a fourth coil end 18c) of the second conductor 18a constituting the second induction coil 18 is grounded via the chamber 11 which is conductive. The first induction coil 17 and the second induction coil 18 generate plasma for processing the target object in the chamber 11 by application of high-frequency power from the high-frequency power supply 19.

The metal cover 25 covers the first induction coil 17 and the second induction coil 18. The metal cover 25 is provided on the upper side of the chamber 11 and electrically connected to the chamber 11. The metal cover 25 is formed in a cylindrical shape with its upper end closed but is not limited thereto. The metal cover 25 may be made of aluminum, for example.

The first support column 27 is provided on the upper side of the central region 13a of the dielectric member 13. The first support column 27 is constituted of an insulator. The first support column 27 is supported by the metal cover 25. The first support column 27 supports the first induction coil 17. The first support column 27 supports the conductive member 26 connected to the second coil end 17c of the first induction coil 17 via a fixing member 28. The conductive member 26 is electrically connected to the metal cover 25 above the first induction coil 17. The conductive member 26 does not extend in a region above the second induction coil 18.

The second support column 29 is positioned on the upper side of the peripheral region 13b of the dielectric member 13. The second support column 29 is constituted of an insulator. The second support column 29 is supported by the metal cover 25. The second support column 29 supports the second induction coil 18.

The electric heater 30 is provided between the dielectric member 13 and the first induction coil 17 and between the dielectric member 13 and the second induction coil 18. The electric heater 30 heats the dielectric member 13 by application of a voltage (e.g., an AC voltage) from the power source section 41. The electric heater 30 includes a first heater 31 that heats the central region 13a of the dielectric member 13, a second heater 34 that heats the peripheral region 13b of the dielectric member 13, and a joint 37 that connects the first heater 31 and the second heater 34.

The first heater 31 includes a first resistor 32 having a first end 32a and a second end 32b. The second heater 34 includes a second resistor 35 having a third end 35a and a fourth end 35b. The first resistor 32 extends in a first direction D1 (in this example, a clockwise direction in FIGS. A and 2B) from the first end 32a to the second end 32b in an arc-shaped manner along a first locus corresponding to the central region 13a. The second resistor 35 extends in the first direction D1 from the third end 35a to the fourth end 35b in an arc-shaped manner along a second locus corresponding to the peripheral region 13b. The first locus and the second locus in the present embodiment are each shaped like a loop of arcs. The first resistor 32 and the second resistor 35 are each formed in a line-like shape. The first resistor 32 and the second resistor 35 are each constituted of a nichrome wire, for example. The first resistor 32 and the second resistor 35 are at least partially covered with the first insulator 33 and the second insulator 36, respectively. The first end 32a of the first heater 31 and the third end 35a of the second heater 34 are connected by the joint 37. That is, the first end 32a and the third end 35a are in electrical conduction via the joint 37. The joint 37 extends in the radial direction of the chamber 11. The first direction D1 is an example of the specific direction in the present disclosure.

The first pusher 38 and the second pusher 39 respectively push the first heater 31 and the second heater 34 against the dielectric member 13. The first pusher 38 is provided between the first support column 27 and the first heater 31. The first pusher 38 includes a first spring 38a that pushes the first heater 31 against the dielectric member 13. The second pusher 39 is provided between the metal cover 25 and the second heater 34. The second pusher 39 includes a second spring 39a that pushes the second heater 34 against the dielectric member 13.

The high-frequency power supply 19 supplies high-frequency power (e.g., AC power at 3 MHz or higher and 30 MHz or lower) to the plasma generation section 16. The high-frequency power supply 19 is connected to the first coil end 17b of the first induction coil 17 and the third coil end 18b of the second induction coil 18 via the matching device 21 and the distributor 22.

The matching device 21 is connected to the high-frequency power supply 19. The matching device 21 is configured to match the impedance (input impedance) of the high-frequency power supply 19 with the impedance (load impedance) of the stage following the matching device 21.

The distributor 22 is connected between the matching device 21 and the plasma generation section 16. The distributor 22 includes a first distribution circuit 23 and a second distribution circuit 24. The first distribution circuit 23 distributes a portion of the high-frequency power output from the high-frequency power supply 19 to the first induction coil 17. The second distribution circuit 24 distributes a portion of the high-frequency power to the second induction coil 18. The first distribution circuit 23 and the second distribution circuit 24 are connected in parallel to each other.

The power source section 41 applies a voltage (e.g., an AC voltage at 50 Hz or 60 Hz) to the electric heater 30. The power source section 41 is connected to the electric heater 30 via a low-pass filter 42. The power source section 41 is connected to the second end 32b of the first heater 31 and the fourth end 35b of the second heater 34 and applies the voltage across the second end 32b and the fourth end 35b.

### Second Embodiment

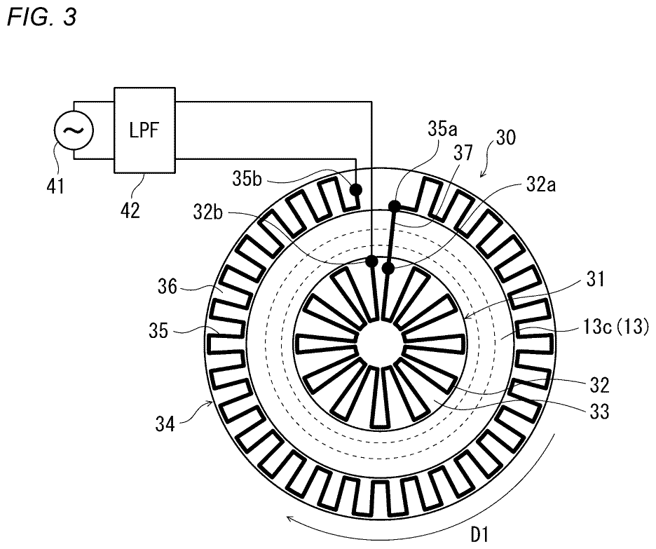

The following describes a second embodiment of the present disclosure. A plasma processing apparatus 10 of the present embodiment differs from that of the first embodiment in the configuration of an electric heater 30. Specifically, in the electric heater 30 of the present embodiment, a first heater 31 (or a first locus) extends in a first direction D1 from a first end 32a to a second end 32b as a whole, while certain parts locally extend in the radial directions, as illustrated in FIG. 3. Also, a second heater 34 (or a second locus) extends in the first direction D1 from a third end 35a to a fourth end 35b as a whole, while certain parts locally extend in the radial directions. The other aspects are the same as those of the first embodiment.

### Third Embodiment

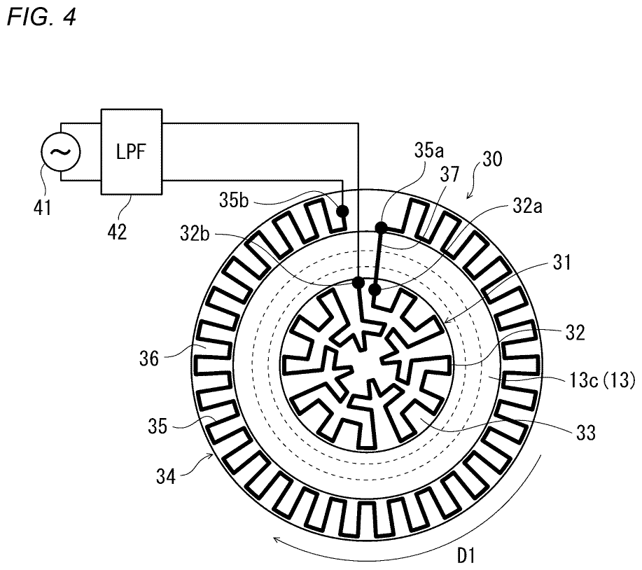

The following describes a third embodiment of the present disclosure. A plasma processing apparatus 10 of the present embodiment differs from that of the first embodiment in the configuration of an electric heater 30. Specifically, in the electric heater 30 of the present embodiment, a first heater 31 (or a first locus) extends in a first direction D1 from a first end 32a to a second end 32b as a whole, while certain parts locally extend in the radial directions or a direction opposite to the first direction D1, as illustrated in FIG. 4. Also, a second heater 34 (or a second locus) extends in the first direction D1 from a third end 35a to a fourth end 35b as a whole, while certain parts locally extend in the radial directions. The other aspects are the same as those of the first embodiment. Note that the second heater 34 illustrated in FIG. 4 may have parts extending in the direction opposite to the first direction D1, similarly to the first heater 31.

### Supplemental Remarks

According to the above description of the embodiments, the following techniques are disclosed.

### Technique 1

A plasma processing apparatus including:
a stage on which a target object is to be placed;
a chamber that houses the stage and that has an opening;
a dielectric member that closes the opening;
an induction coil that is provided on a side of the dielectric member opposite the stage and that generates plasma for processing the target object by application of high-frequency power;
an electric heater that is provided between the dielectric member and the induction coil and that heats the dielectric member; and
a power source section that applies a voltage to the electric heater,
wherein the dielectric member has a first region and a second region surrounding the first region,
the electric heater includes:
   a first heater that heats the first region;
   a second heater that heats the second region; and
   a joint that connects the first heater and the second heater,
the first heater includes a first resistor having a first end and a second end,
the second heater includes a second resistor having a third end and a fourth end,
the first resistor extends in a specific direction from the first end to the second end along a first locus corresponding to the first region, the specific direction being one of circumferential directions,
the second resistor extends in the specific direction from the third end to the fourth end along a second locus corresponding to the second region,
the joint connects the first end and the third end, and
the power source section applies the voltage between the second end and the fourth end.

### Technique 2

The plasma processing apparatus according to Technique 1, wherein the dielectric member has an annular groove formed in a surface thereof facing the induction coil between first region and the second region.

### Technique 3

The plasma processing apparatus according to Technique 2, wherein at least a part of the induction coil is positioned in the annular groove.

### Technique 4

The plasma processing apparatus according to any one of Techniques 1 to 3, wherein the power source section is connected to the electric heater via a low-pass filter.

### Technique 5

The plasma processing apparatus according to any one of Techniques 1 to 4, wherein the joint extends in radial directions of the chamber.

The present disclosure can be utilized in plasma processing apparatus.

### Reference Numerals

10: Plasma processing apparatus
   11: Chamber
      11a: Opening
      11b: Exhaust port
   12: Stage
      12a: Placement surface
   13: Dielectric member
      13a: Central region (first region)
      13b: Peripheral region (second region)
      13c: Annular groove
   14: Cover
      14a: First gas hole
      14b: Second gas hole
   15: Gas introduction path
      15a: First gas introduction path
      15b: Second gas introduction path
   16: Plasma generation section
      17: First induction coil (induction coil)
         17a: First conductor
         17b: First coil end
         17c: Second coil end
      18: Second induction coil (induction coil)
         18a: Second conductor
         18b: Third coiled end
         18c: Fourth coil end
   19: High-frequency power supply
   21: Matching device
   22: Distributor
      23: First distribution circuit
      24: Second distribution circuit
   25: Metal cover
   26: Conductive member
   27: First support column
   28: Fixing member
   29: Second support column
   30: Electric heater
      31: First heater
         32: First resistor
         32a: First end
         32b: Second end
         33: First insulator
         34: Second heater
         35: Second resistor
         35a: Third end
         35b: Fourth end
         36: Second insulator
      37: Joint
   38: First pusher
      38a: First spring
   39: Second pusher
      9a: Second spring
   41: Power source section
   42: Low-pass filter
D1: First direction

What is claimed is:

1. A plasma processing apparatus comprising:
a stage on which a target object is to be placed;
a chamber that houses the stage and that has an opening;
a dielectric member that closes the opening;
an induction coil that is provided on a side of the dielectric member opposite the stage and that generates plasma for processing the target object by application of high-frequency power;
an electric heater that is provided between the dielectric member and the induction coil and that heats the dielectric member; and
a power source section that applies a voltage to the electric heater,
wherein the dielectric member has a first region and a second region surrounding the first region,
the electric heater includes:
a first heater that heats the first region;
a second heater that heats the second region; and
a joint that connects the first heater and the second heater,
the first heater includes a first resistor having a first end and a second end,
the second heater includes a second resistor having a third end and a fourth end,
the first resistor extends in a specific direction from the first end to the second end along a first locus corresponding to the first region, the specific direction being one of circumferential directions,
the second resistor extends in the specific direction from the third end to the fourth end along a second locus corresponding to the second region,
the joint connects the first end and the third end, and
the power source section applies the voltage between the second end and the fourth end.

2. The plasma processing apparatus according to claim 1,
wherein the dielectric member has an annular groove formed in a surface thereof facing the induction coil between first region and the second region.

3. The plasma processing apparatus according to claim 2,
wherein at least a part of the induction coil is positioned in the annular groove.

4. The plasma processing apparatus according to claim 1,
wherein the power source section is connected to the electric heater via a low-pass filter.

5. The plasma processing apparatus according to claim 1,
wherein the joint extends in radial directions of the chamber.
